(19) United States
(12) Patent Application Publication
(10) Pub. No.: US 2017/0318374 A1
(43) Pub. Date: Nov. 2, 2017

(54) HEADSET, AN APPARATUS AND A METHOD WITH AUTOMATIC SELECTIVE VOICE PASS-THROUGH

(71) Applicant: Microsoft Technology Licensing, LLC, Redmond, WA (US)

(72) Inventors: André Dolenc, Espoo (FI); Tuomas Juhola, Espoo (FI)

(21) Appl. No.: 15/144,790

(22) Filed: May 2, 2016

(51) Int. Cl. H04R 1/10; H03G 3/30; G10K 11/178; H04R 1/08; H04R 3/00; H04R 29/00

(52) U.S. Cl. CPC H04R 1/1041; H04R 3/00; H04R 29/004; G10K 11/178; H04R 1/08; H03G 3/3005; H04R 2420/07

(57) ABSTRACT

In one example, a headset comprises a microphone; an earpiece that is configured to output audio based on one or more of the following: a first audio signal from a connected host device and associated with an application type and a second audio signal from the microphone, when present; a noise reduction module that is configured to reduce ambient noise; a speech detection module that is configured to detect whether a headset user is talking; a voice pass-through module that is configured to pass external voices captured with the microphone as the second audio signal to the earpiece, when activated; and a controller that is configured to activate the voice pass-through module in response to the speech detection module detecting the headset user talking, when uplink audio is off.

### BACKGROUND

Various electronic devices, including mobile communication devices typically allow the user to utilize a headset for receiving and transmitting audio. These headsets often implement various audio modes, including voice pass-through to allow the user to hear other people nearby talking without removing the headset. Using such audio modes requires interaction from the user in order to activate and deactivate them.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

In one example, a headset comprises a microphone. The headset further comprises an earpiece that is configured to output audio based on one or more of the following: a first audio signal from a connected host device and associated with an application type and a second audio signal from the microphone, when present. The headset further comprises a noise reduction module that is configured to reduce ambient noise. The headset further comprises a speech detection module that is configured to detect whether a headset user is talking. The headset further comprises a voice pass-through module that is configured to pass external voices captured with the microphone as the second audio signal to the earpiece, when activated. The headset further comprises a controller that is configured to activate the voice pass-through module in response to the speech detection module detecting the headset user talking, when uplink audio is off.

In another example, an apparatus and a method have been discussed along with the features of the headset.

Many of the attendant features will be more readily appreciated as the same becomes better understood by reference to the following detailed description considered in connection with the accompanying drawings.

### DESCRIPTION OF THE DRAWINGS

The present description will be better understood from the following detailed description read in light of the accompanying drawings, wherein:

FIG. 1 is an example block diagram of a headset in accordance with an example embodiment;

FIG. 2 is another example block diagram of a headset including an apparatus in accordance with an example embodiment;

FIGS. 3A-3D are example flow diagrams of methods in accordance with example embodiments; and

FIG. 4 illustrates an example block diagram of a host device in accordance with an example embodiment.

Like reference numerals are used to designate like parts in the accompanying drawings.

### DETAILED DESCRIPTION

The detailed description provided below in connection with the appended drawings is intended as a description of the present examples and is not intended to represent the only forms in which the present examples may be constructed or utilized. The description sets forth the functions of the examples and the sequence of operations for constructing and operating the examples. However, the same or equivalent functions and sequences may be accomplished by different examples.

At least some of the disclosed examples may allow a selectively automatic way to activate and deactivate audio modes utilized by a headset. At least some of the disclosed examples may allow a selectively automatic way to activate and deactivate audio modes utilized by a headset. At least some of the disclosed examples may allow the headset user to hear his/her own voice and the voice of someone else nearby he/she is talking with via the audio output by the headset earpiece(s). Accordingly, at least some of the disclosed examples may allow the headset user to hear his/her own voice and the voice of someone else nearby clearly without the headset earpiece(s) and/or the noise cancellation of the headset muffling or attenuating these voices. Accordingly, the headset user has no need to remove the headset or manually lower the headset volume.

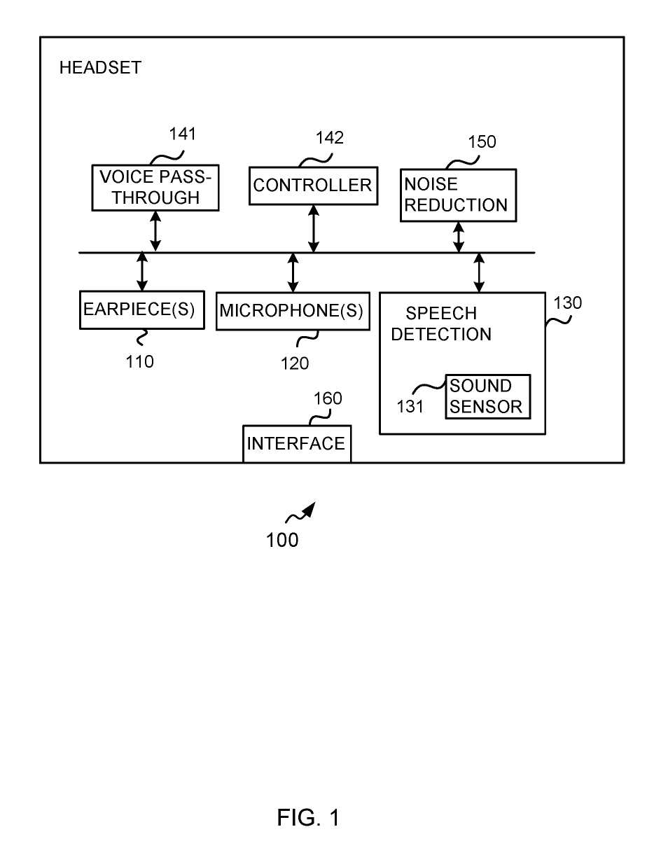

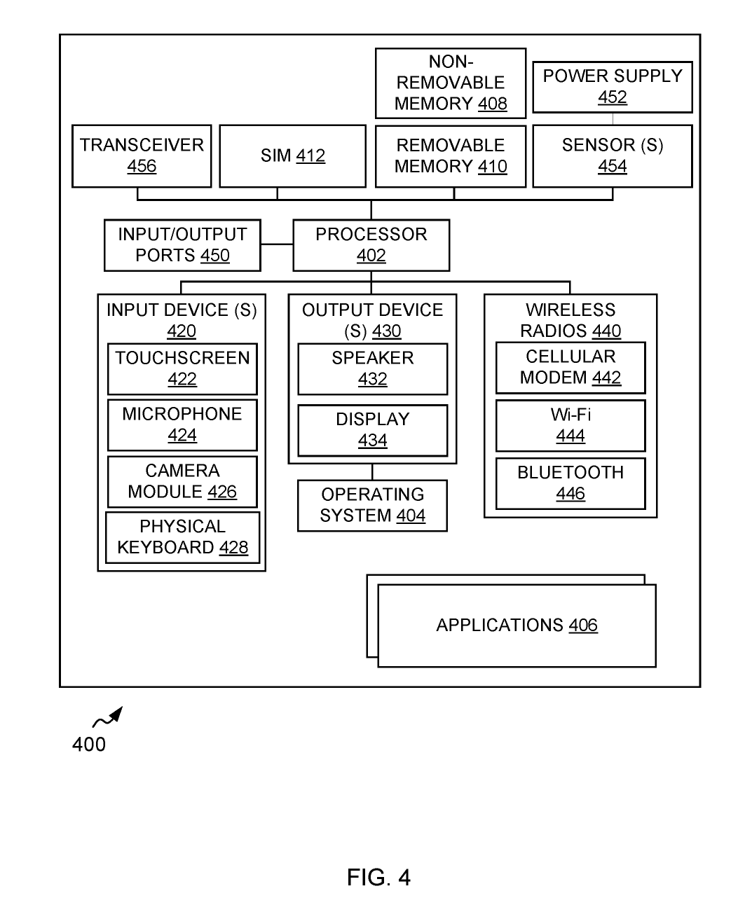

FIG. 1 illustrates a headset 100 in accordance with an example embodiment. The headset 100 may be employed, for example, with the host device 400 of FIG. 4. However, it should be noted that the headset 100 may also be employed with a variety of other devices and apparatuses, and therefore, embodiments should not be limited to application on devices and apparatuses such as the host device 400 of FIG. 4. Furthermore, it should be noted that at least some of the elements described below may not be mandatory and thus some may be omitted in certain embodiments.

The headset 100 comprises a noise reduction module 150 that is configured to reduce ambient noise. The noise reduction module 150 may comprise e.g. an active noise cancellation (ANC) unit and/ or a passive noise cancellation unit. Passive noise cancellation utilizes non-powered techniques, such as soundproofing in earpiece(s) 110 to reduce ambient noise and/or sounds. In contrast, active noise cancellation utilizes powered techniques, such as techniques that measure ambient sound, generate a waveform that is the exact negative of the ambient sound, and mix it with a given audio signal, such as the first audio signal described below. In an embodiment, passive noise cancellation may be utilized to reduce high frequencies, and active noise cancellation may be utilized to reduce low frequencies.

In an embodiment, the active noise cancellation unit may utilize feed-forward active noise cancellation techniques and/or feed-back active noise cancellation techniques. In a feed-forward system, a microphone exposed to the environment listens to the ambient noise. The system's transfer function simulates and subtracts the noise from the audio signal fed to the speaker inside the unit. A feedback system by contrast uses a microphone beside the speaker inside the ear cup or bud. Rather than sensing the ambient noise around the wearer's head, it listens to the actual noise at the ear.

The headset 100 further comprises one or more microphones 120. At least one of the microphones 120 is arranged so that it is able to capture voices external to the headset 100, including the headset user's voice or speech and voices from people nearby. Furthermore, one or more microphones may be utilized by the active noise cancellation unit of the noise reduction module 150. At least some of the microphones utilized by the active noise cancellation unit may be arranged inside one or more earpieces. At least some of the microphones 120 may be positioned in different directions.

The headset 100 further comprises one or more earpieces 110 that are configured to output audio based on a first audio signal from a connected host device and/or a second audio signal from the microphone, when at least one of the first or second audio signals are present. The audio being output is noise reduced by the noise reduction module 150. In an embodiment, the headset comprises two earpieces 110 one of which may provide mono sound for downlink audio and the other one may provide mono sound for uplink audio in two-way applications such as telephone applications, whereas for one-way applications the two earpieces 110 may provide stereo sound for downlink audio, for instance. Herein, uplink refers to the communication direction away from the headset towards the host device and, where applicable, onward to e.g. communication party/parties the headset user is conversing with. Correspondingly, downlink refers to the opposite direction, i.e. the communication direction towards the headset from the host device and, where applicable, from e.g. the communication party/parties the headset user is conversing with or from any other third party. Herein, the term “earpiece” is used to refer to over-the-ear type earpieces (such as earcups), on-ear type earpieces, and in-ear type earpieces (such as earbuds).

The first audio signal is associated with an application type. The application type may comprise e.g. a call audio (such as audio related to a telephone call or an internet call, including conference calls) or non-call audio (such as music or multimedia audio). The controller 142 (described below in more detail) may be configured to determine the associated application type based on information about a connection interface 160 utilized between the headset 100 and the host device. The connection interface 160 may comprise a wireless interface, such as a Bluetooth interface. Alternatively, the connection interface 160 may comprise a wired interface, such as a universal serial bus (USB) interface. The information about a connection interface 160 may comprise e.g. information about a Bluetooth profile negotiated between the headset 100 and the host device that describe the type of applications or use cases for the headset 100 and the host device, or information about a used USB connection. Bluetooth profiles may include e.g. an advanced audio distribution profile (A2DP) for streaming multimedia audio, and a hands-free profile (HFP) for telephony applications. Accordingly, if the first audio signal relates to e.g. a phone call received to the headset over a Bluetooth connection, the controller 142 may be configured to determine this from the used Bluetooth hands-free profile.

The headset 100 further comprises a speech detection module 130 that is configured to detect whether a user of the headset 100 is talking. The speech detection module 130 may comprise a sound sensor 131. The sound sensor 131 may comprise a jawbone sensor placed on the jaw of the headset user that is configured to detect whether the user of the headset 100 is talking e.g. via jawbone vibrations. Alternatively or in addition, the sound sensor 131 may comprise one or more of the microphones 120.

The headset 100 further comprises a voice pass-through module 141 that is configured to pass external voices captured with the microphone 120 as the second audio signal to the earpiece 110, when the voice pass-through module 141 is activated. The voice pass-through module 141 may be implemented at least in part with elements or components of the active noise cancellation unit of the noise reduction module 150. Alternatively or in addition, the voice pass-through module 141 may be implemented at least in part with e.g. digital filtering elements or components. The voice pass-through module 141 may be configured to pass external voices that are substantially within the frequency range of normal human speech (such as approximately 300 hertz (Hz)-3400 Hz).

The headset 100 further comprises the controller 142 that is configured to activate the voice pass-through module 141 in response to the speech detection module 130 detecting that the headset user is talking, when the uplink audio is off. The controller 142 may be further configured to deactivate the voice pass-through module 141 in response to the uplink audio being unmuted (in cases where the uplink audio was off due to being muted). Alternatively or in addition, the controller 142 may be further configured to deactivate the voice pass-through module 141 in response to a user input or interaction (such as a button press or a tap on a touch panel, or the like). Alternatively or in addition, the controller 142 may be further configured to deactivate the voice pass-through module 141 in response to a predetermined time limit being exceeded without the speech detection module 130 detecting the headset user still talking. As a result of the deactivation of the voice pass-through module 141, external voices captured with the microphone 120 are not passed for mixing to the audio output anymore. As a further result of the deactivation of the voice pass-through module 141, the headset may return to an audio mode it was utilizing before the activation of the voice pass-through module 141. The controller 142 may be further configured to store information about the audio mode utilized before the activation of the voice pass-through module 141, thereby allowing the return to it.

The controller 142 may be further configured to increase and/or decrease the volume level of the first audio signal and/or the second audio signal while the voice pass-through module 141 is activated. In an embodiment, the controller 142 may be further configured to increase the volume level of the second audio signal and/or decrease the volume level of the first audio signal while the voice pass-through module 141 is activated in order to improve the audibility of the second audio signal at the expense of the first audio signal. In an embodiment, the controller 142 may be further configured to increase the volume level of the second audio signal and/or decrease the volume level of the first audio signal while the voice pass-through module 141 is activated so that the volume level difference is at least substantially 20 decibels (dB). In order to control the volume levels, the controller 142 may be further configured to measure or monitor the volume levels of the first audio signal and the second audio signal.

The controller 142 may be further configured to pause the playback of the first audio signal while the voice pass-through module 141 is activated, in cases where the first audio signal is of a type that can be paused, such as a non-call audio signal, in order to improve the audibility of the second audio signal at the expense of the first audio signal.

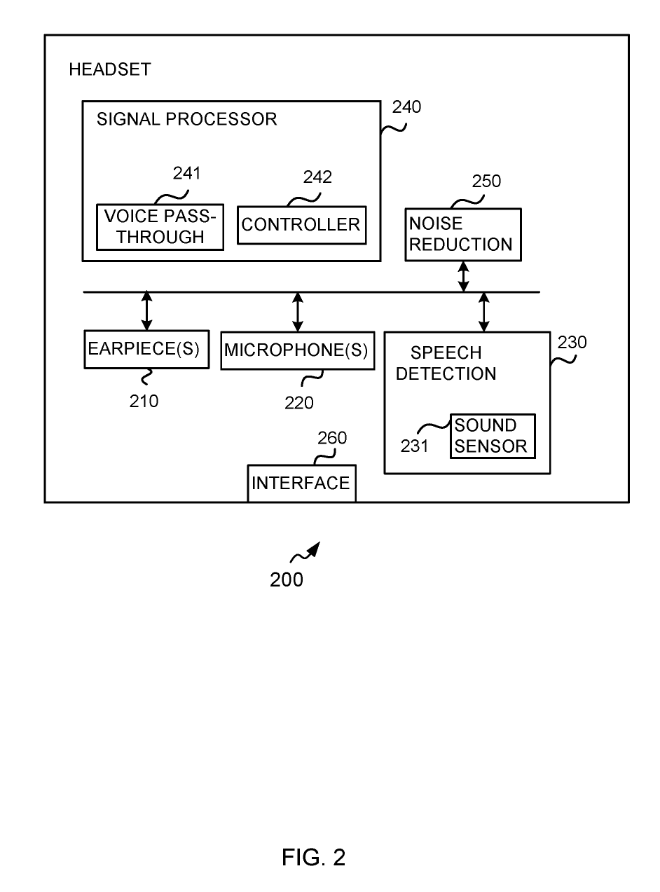

FIG. 2 illustrates a headset 200 in accordance with an example embodiment. The headset 200 may be employed, for example, with the host device 400 of FIG. 4. However, it should be noted that the headset 200 may also be employed with a variety of other devices and apparatuses, and therefore, embodiments should not be limited to application on devices and apparatuses such as the host device 400 of FIG. 4. Furthermore, it should be noted that at least some of the elements described below may not be mandatory and thus some may be omitted in certain embodiments.

In the example of FIG. 2, the functionalities and properties of the one or more earpieces 210, the one or more microphones 220, the speech detection module 230, the voice pass-through module 241, the controller 242, the noise reduction module 250, and the connection interface 260 are substantially similar to those of their counterparts in the example of FIG. 1, so their descriptions are not repeated here in detail.

In the example of FIG. 2, the headset 200 further comprises an apparatus 240 (such as a signal processor, a microcontroller, or the like) that includes the voice pass-through module 241 and the controller 242. In an embodiment, the apparatus 240 may also include at least a part of the active noise cancellation unit of the noise reduction module 250.

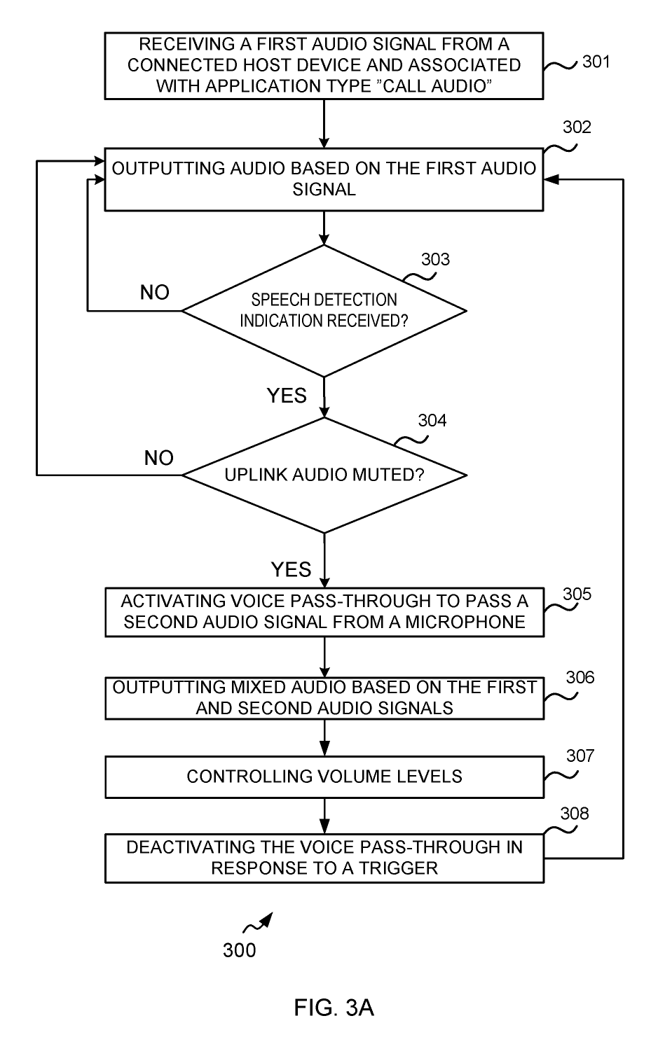

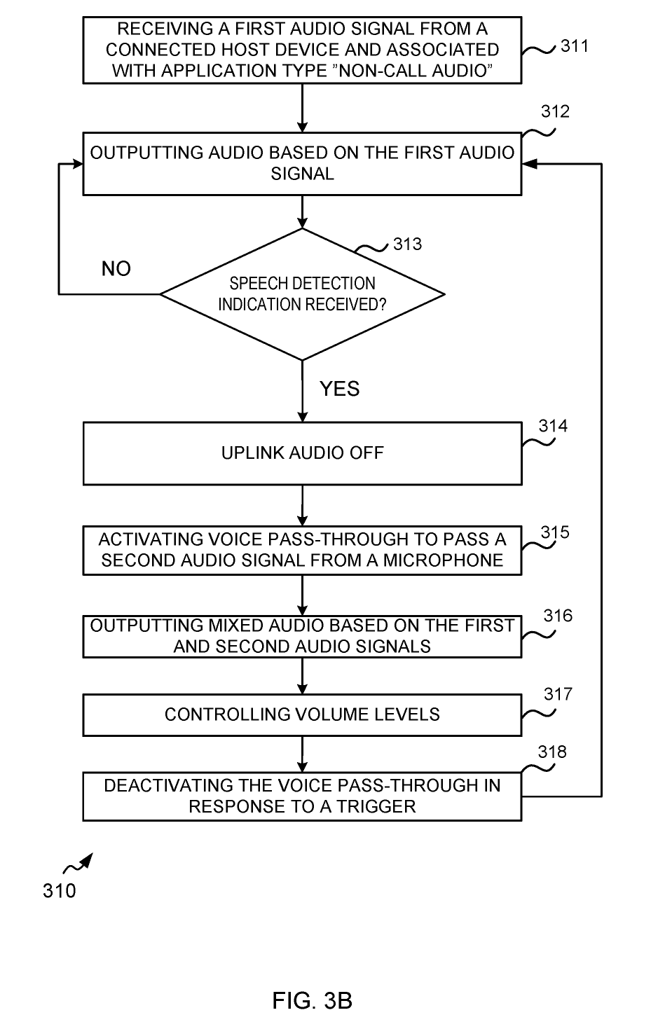

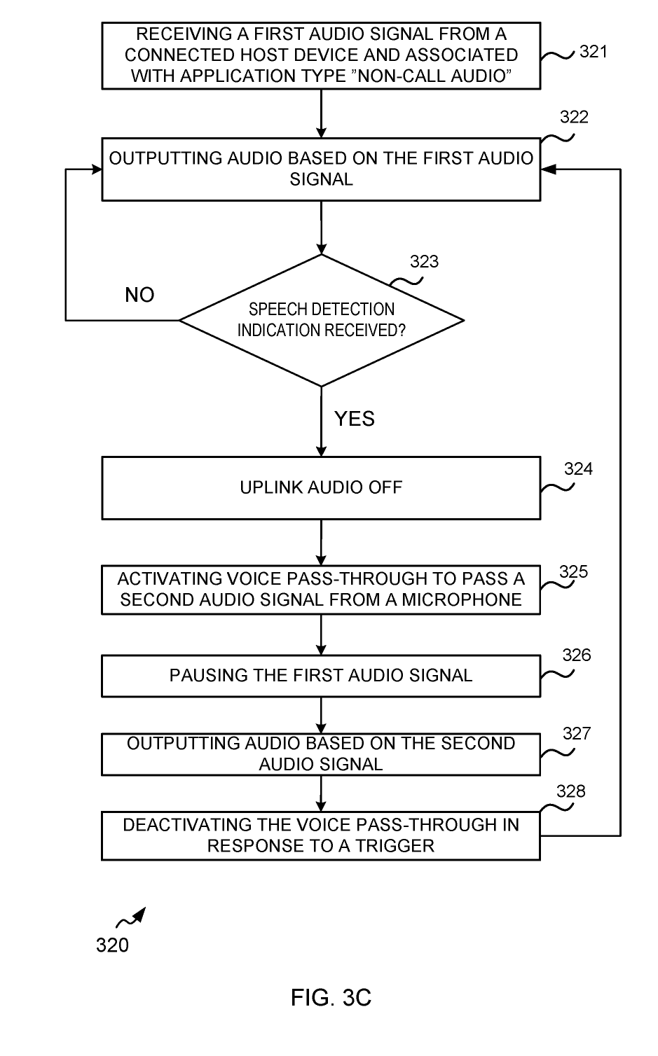

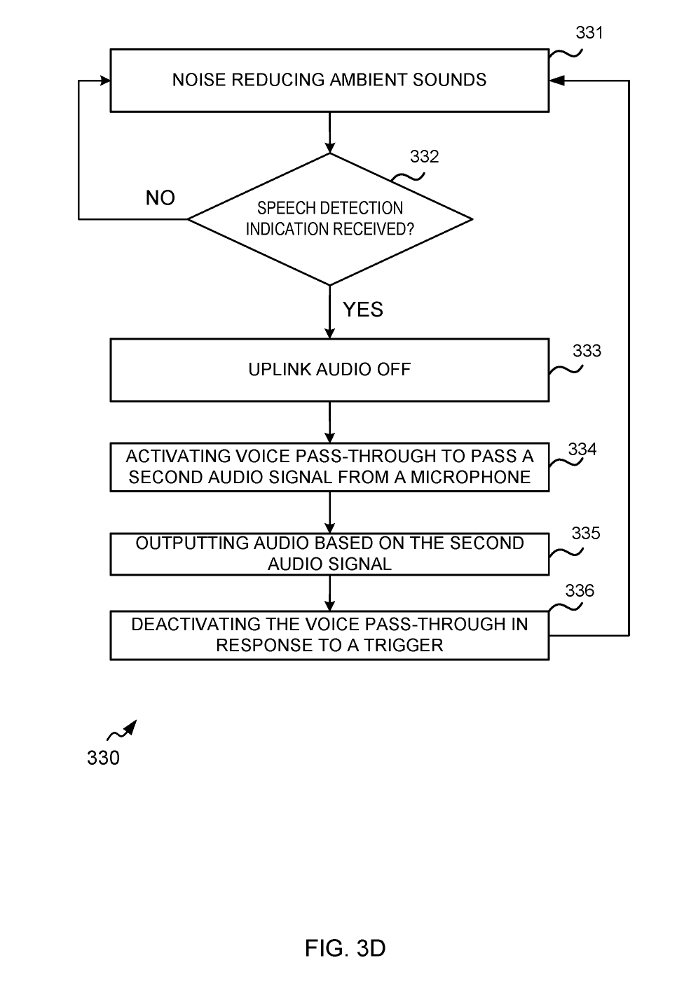

FIG. 3A is an example flow diagram of a method 300 in accordance with an example embodiment. At operation 301, a first audio signal is received at a headset from a host device connected (via a wired connection or a wireless connection) to the headset. The first audio signal is associated with an application type. The first audio signal, its application type, the headset and the host device have been described in more detail above in connection with FIG. 1. In the embodiment of FIG. 3A, the application type comprises “call audio”, and the first audio signal is related to a conference call that may be a telephone call or an internet call. Accordingly, uplink audio comprises transmission of the headset user's voice to the other participants of the conference call, and downlink audio comprises transmission of the voices of the other participants to the headset user.

The headset controller may determine whether the application type associated with the first audio signal belongs to a group of predetermined application types. Here, the group of predetermined application types includes call audio and non-call audio. Since the first audio signal is related to a conference call, its application type is determined to be call audio. This determination may utilize information about the connection interface utilized between the headset 100 and the host device, as discussed in connection with FIG. 1.

At operation 302, audio based on the first audio signal is output by the headset. In other words, in the embodiment of FIG. 3A, the headset user hears the voices of the other participants. Furthermore, ambient sounds are being noise reduced by a headset noise reduction unit.

At operation 303, if an indication is received at the headset controller from the headset speech detection module that the headset user is talking, the method proceeds to operation 304. Otherwise, the method returns to operation 302.

The headset controller determines whether uplink audio has been muted (e.g. via interaction or command by the headset user), operation 304. If the uplink audio has not been muted, it indicates that the headset user wishes to speak with one or more of the other participants of the conference call. Accordingly, the method returns to operation 302 allowing voices of the conference call participants to be heard normally with the headset.

However, if the uplink audio has been muted by the headset user, it indicates that the headset user wishes to speak with someone else who is not a participant in the call, i.e. with someone else who is likely at the vicinity of the headset user. Accordingly, the method proceeds to operation 305.

At operation 305, the voice pass-through module of the headset is activated by the headset controller. As a result, the voice pass-through module passes external voices captured with the headset microphone as a second audio signal for mixing to the audio output by the headset earpiece at operation 306. Accordingly, the headset user hears his/her own voice and the voice of the non-call participant via the audio output by the headset earpiece(s). In other words, the headset user hears his/her own voice and the voice of the non-call participant clearly without the headset earpiece(s) and/or the noise cancellation of the headset muffling or attenuating these voices. Accordingly, the headset user has no need to remove the headset or manually lower the headset volume.

At operation 307, the volume level of the first audio signal and/or the second audio signal is automatically increased and/or decreased by the headset controller while the voice pass-through module is activated. For example, the volume level of the second audio signal may be increased and/or the volume level of the first audio signal may be decreased in order to improve the audibility of the discussion with the non-call participant at the expense of the call. In an embodiment, the volume level of the second audio signal may be increased and/or the volume level of the first audio signal may be decreased so that the volume level difference is at least substantially 20 decibels (dB).

At operation 308, the voice pass-through module is automatically deactivated by the headset controller, and the method may return to operation 302 e.g. for the remaining duration of the call. The deactivation may be performed in response to the uplink audio is unmuted e.g. by the user. This indicates that the headset user is finished with speaking with someone else who is not a participant in the call. Alternatively, the deactivation may be performed in response to a user input, or a predetermined time limit being exceeded without the speech detection module detecting the headset user still talking.

FIG. 3B is an example flow diagram of a method 310 in accordance with an example embodiment. At operation 311, a first audio signal is received at a headset from a host device connected (via a wired connection or a wireless connection) to the headset. The first audio signal is associated with an application type. The first audio signal, its application type, the headset and the host device have been described in more detail above in connection with FIG. 1. In the embodiment of FIG. 3B, the application type comprises “non-call audio”, and the first audio signal is related e.g. to music or multimedia being streamed from the host device. Accordingly, uplink audio is off (i.e. absent), and downlink audio comprises the music or multimedia audio being streamed to the headset.

The headset controller may determine whether the application type associated with the first audio signal belongs to a group of predetermined application types. Here, the group of predetermined application types includes call audio and non-call audio. Since the first audio signal is related to the music or multimedia audio being streamed to the headset, its application type is determined to be non-call audio. This determination may utilize information about the connection interface utilized between the headset 100 and the host device, as discussed in connection with FIG. 1.

At operation 312, audio based on the first audio signal is output by the headset. In other words, in the embodiment of FIG. 3B, the headset user hears the music or multimedia audio being streamed to the headset. Furthermore, ambient sounds are being noise reduced by a headset noise reduction unit.

At operation 313, if an indication is received at the headset controller from the headset speech detection module that the headset user is talking, the method proceeds to operation 314. Otherwise, the method returns to operation 312.

The headset controller determines that the uplink audio is off (absent), operation 314. The indication is that the headset user wishes to speak with someone else who is likely at the vicinity of the headset user. Accordingly, the method proceeds to operation 315.

At operation 315, the voice pass-through module of the headset is activated by the headset controller. As a result, the voice pass-through module passes external voices captured with the headset microphone as a second audio signal for mixing to the audio output by the headset earpiece at operation 316. Accordingly, the headset user hears his/her own voice and the voice of someone else via the audio output by the headset earpiece(s). In other words, the headset user hears his/her own voice and the voice of someone else clearly without the headset earpiece(s) and/or the noise cancellation of the headset muffling or attenuating these voices. Accordingly, the headset user has no need to remove the headset or manually lower the headset volume.

At operation 317, the volume level of the first audio signal and/or the second audio signal is automatically increased and/or decreased by the headset controller while the voice pass-through module is activated. For example, the volume level of the second audio signal may be increased and/or the volume level of the first audio signal may be decreased in order to improve the audibility of the discussion with someone else at the expense of the music or multimedia audio being streamed to the headset. In an embodiment, the volume level of the second audio signal may be increased and/or the volume level of the first audio signal may be decreased so that the volume level difference is at least substantially 20 decibels (dB).

At operation 318, the voice pass-through module is automatically deactivated by the headset controller, and the method may return to operation 312 e.g. for the remaining duration of the music/multimedia audio listening session. The deactivation may be performed in response to a user input, or a predetermined time limit being exceeded without the speech detection module detecting the headset user still talking.

FIG. 3C is an example flow diagram of a method 320 in accordance with an example embodiment. At operation 321, a first audio signal is received at a headset from a host device connected (via a wired connection or a wireless connection) to the headset. The first audio signal is associated with an application type. The first audio signal, its application type, the headset and the host device have been described in more detail above in connection with FIG. 1. In the embodiment of FIG. 3C, the application type comprises “non-call audio”, and the first audio signal is related e.g. to music or multimedia being streamed from the host device. Accordingly, uplink audio is off (i.e. absent), and downlink audio comprises the music or multimedia audio being streamed to the headset.

The headset controller may determine whether the application type associated with the first audio signal belongs to a group of predetermined application types. Here, the group of predetermined application types includes call audio and non-call audio. Since the first audio signal is related to the music or multimedia audio being streamed to the headset, its application type is determined to be non-call audio. This determination may utilize information about the connection interface utilized between the headset 100 and the host device, as discussed in connection with FIG. 1.

At operation 322, audio based on the first audio signal is output by the headset. In other words, in the embodiment of FIG. 3C, the headset user hears the music or multimedia audio being streamed to the headset. Furthermore, ambient sounds are being noise reduced by a headset noise reduction unit.

At operation 323, if an indication is received at the headset controller from the headset speech detection module that the headset user is talking, the method proceeds to operation 324. Otherwise, the method returns to operation 322.

The headset controller determines that the uplink audio is off (absent), operation 324. The indication is that the headset user wishes to speak with someone else who is likely at the vicinity of the headset user. Accordingly, the method proceeds to operation 325.

At operation 325, the voice pass-through module of the headset is activated by the headset controller. As a result, the voice pass-through module passes external voices captured with the headset microphone as a second audio signal to the headset earpiece. Furthermore, the first audio signal is paused e.g. by the headset controller while the voice pass-through module is activated, operation 326. Accordingly, audio based on the second audio signal is output by the headset earpiece, operation 327.

Accordingly, the headset user hears his/her own voice and the voice of someone else via the audio output by the headset earpiece(s). In other words, the headset user hears his/her own voice and the voice of someone else clearly without the headset earpiece(s) and/or the noise cancellation of the headset muffling or attenuating these voices. Accordingly, the headset user has no need to remove the headset or manually lower the headset volume.

At operation 328, the voice pass-through module is automatically deactivated by the headset controller, and the method may return to operation 322 e.g. for the remaining duration of the music/multimedia audio listening session. The deactivation may be performed in response to a user input, or a predetermined time limit being exceeded without the speech detection module detecting the headset user still talking.

FIG. 3D is an example flow diagram of a method 330 in accordance with an example embodiment. In the embodiment of FIG. 3D, no first audio signal is being received at a headset from a host device connected to the headset. Instead, the headset is being used for providing silence from ambient sounds.

At operation 331, ambient sounds are being noise reduced by a headset noise reduction unit.

At operation 332, if an indication is received at the headset controller from the headset speech detection module that the headset user is talking, the method proceeds to operation 333. Otherwise, the method returns to operation 331.

The headset controller determines that the uplink audio is off (absent), operation 333. The indication is that the headset user wishes to speak with someone else who is likely at the vicinity of the headset user. Accordingly, the method proceeds to operation 334.

At operation 334, the voice pass-through module of the headset is activated by the headset controller. As a result, the voice pass-through module passes external voices captured with the headset microphone as a second audio signal to the headset earpiece. Accordingly, audio based on the second audio signal is output by the headset earpiece, operation 335.

Accordingly, the headset user hears his/her own voice and the voice of someone else via the audio output by the headset earpiece(s). In other words, the headset user hears his/her own voice and the voice of someone else clearly without the headset earpiece(s) and/or the noise cancellation of the headset muffling or attenuating these voices. Accordingly, the headset user has no need to remove the headset or manually lower the headset volume.

At operation 336, the voice pass-through module is automatically deactivated by the headset controller, and the method may return to operation 331 e.g. for the remaining duration of the silence session. The deactivation may be performed in response to a user input, or a predetermined time limit being exceeded without the speech detection module detecting the headset user still talking.

FIG. 4 is a schematic block diagram of a host device 400 capable of implementing embodiments of the techniques described herein. It should be understood that the host device 400 as illustrated and hereinafter described is merely illustrative of one type of apparatus or a host device and should not be taken to limit the scope of the embodiments. As such, it should be appreciated that at least some of the components described below in connection with the host device 400 may be optional and thus in an example embodiment may include more, less or different components than those described in connection with the example embodiment of FIG. 4. As such, among other examples, the host device 400 could be any of apparatuses capable of interacting with a headset. For example, the host device 400 may be implemented e.g. as a smartphone, a tablet computer, a laptop computer, a desktop computer, a personal media player, or a game console.

The illustrated host device 400 includes a controller or a processor 402 (i.e. a signal processor, microprocessor, ASIC, or other control and processing logic circuitry) for performing such tasks as signal coding, data processing, input/output processing, power control, and/or other functions. An operating system 404 controls the allocation and usage of the components of the host device 400 and support for one or more application programs 406. The application programs 406 can include common mobile applications, for instance, telephony applications, email applications, calendars, contact managers, web browsers, messaging applications, or any other application.

The illustrated host device 400 includes one or more memory components, for example, a non-removable memory 408 and/or removable memory 410. The non-removable memory 408 may include RAM, ROM, flash memory, a hard disk, or other well-known memory storage technologies. The removable memory 410 may include flash memory or smart cards. The one or more memory components may be used for storing data and/or code for running the operating system 404 and the applications 406. Example of data may include web pages, text, images, sound files, image data, video data, or other data sets to be sent to and/or received from one or more network servers or other devices via one or more wired or wireless networks. The host device 400 may further include a subscriber identity module (SIM) 412. The SIM 412 typically stores information elements related to a mobile subscriber. A SIM is well known in Global System for Mobile Communications (GSM) communication systems, Code Division Multiple Access (CDMA) systems, or with third-generation (3G) wireless communication protocols such as Universal Mobile Telecommunications System (UMTS), CDMA1000, wideband CDMA (WCDMA) and time division-synchronous CDMA (TD-SCDMA), or with fourth-generation (4G) wireless communication protocols such as LTE (Long-Term Evolution). The SIM 412 may comprise a virtual SIM. Furthermore, multiple SIMs may be utilized.

The host device 400 can support one or more input devices 420 and one or more output devices 430. Examples of the input devices 420 may include, but are not limited to, a touchscreen 422 (i.e., capable of capturing finger tap inputs, finger gesture inputs, multi-finger tap inputs, multi-finger gesture inputs, or keystroke inputs from a virtual keyboard or keypad), a microphone 424 (i.e., capable of capturing voice input), a camera module 426 (i.e., capable of capturing still picture images and/or video images) and a physical keyboard 428. The camera module 426 may include the camera module 200 of FIG. 2. Examples of the output devices 430 may include, but are not limited to a speaker 432 and a display 434. Other possible output devices (not shown) can include piezoelectric or other haptic output devices. Some devices can serve more than one input/output function. For example, the touchscreen 422 and the display 434 can be combined into a single input/output device.

In an embodiment, the host device 400 may comprise a wireless radio(s) 440. The wireless radio(s) 440 can support two-way communications between the processor 402 and external devices, as is well understood in the art. The wireless radio(s) 440 are shown generically and can include, for example, a cellular modem 442 for communicating at long range with the mobile communication network, a Wi-Fi radio 444 for communicating at short range with a local wireless data network or router, and/or a BLUETOOTH radio 446. The cellular modem 442 is typically configured for communication with one or more cellular networks, such as a GSM/3G/4G network for data and voice communications within a single cellular network, between cellular networks, or between the mobile device and a public switched telephone network (PSTN).

The host device 400 can further include one or more input/output ports 450, a power supply 452, one or more sensors 454, for example an accelerometer, a gyroscope, a compass, or an infrared proximity sensor for detecting the orientation or motion of the host device 400, and a transceiver 456 (for wirelessly transmitting analog or digital signals). The illustrated components are not required or all-inclusive, as any of the components shown can be deleted and other components can be added.

Computer executable instructions may be provided using any computer-readable media that is accessible by computing based devices. Computer-readable media may include, for example, computer storage media such as memory and communications media. Computer storage media, such as memory includes volatile and non-volatile, removable and non-removable media implemented in any method or technology for storage of information such as computer readable instructions, data structures, program modules or the like. Computer storage media includes, but is not limited to, RAM, ROM, EPROM, EEPROM, flash memory or other memory technology, CD-ROM, digital versatile disks (DVD) or other optical storage, magnetic cassettes, magnetic tape, magnetic disk storage or other magnetic storage devices, or any other non-transmission medium that can be used to store information for access by a computing device. In contrast, communication media may embody computer readable instructions, data structures, program modules, or the like in a modulated data signal, such as a carrier wave, or other transport mechanism. As defined herein, computer storage media does not include communication media. Therefore, a computer storage medium should not be interpreted to be a propagating signal per se. Although the computer storage media is shown within the computing based devices it will be appreciated that the storage may be distributed or located remotely and accessed via a network or other communication link, for example by using a communication interface.

At least some of the examples disclosed in FIGS. 1-4 are able to provide a selectively automatic way to activate and deactivate audio modes utilized by a headset. At least some of the examples disclosed in FIGS. 1-4 allow the headset user to hear his/her own voice and the voice of someone else nearby he/she is talking with via the audio output by the headset earpiece(s). Accordingly, at least some of the examples disclosed in FIGS. 1-4 allow the headset user to hear his/her own voice and the voice of someone else nearby clearly without the headset earpiece(s) and/or the noise cancellation of the headset muffling or attenuating these voices. Accordingly, the headset user has no need to remove the headset or manually lower the headset volume.

An embodiment of a headset comprises a microphone; an earpiece configured to output audio based on one or more of the following: a first audio signal from a connected host device and associated with an application type and a second audio signal from the microphone, when present; a noise reduction module configured to reduce ambient noise; a speech detection module configured to detect whether a headset user is talking; a voice pass-through module configured to pass external voices captured with the microphone as the second audio signal to the earpiece, when activated; and a controller configured to activate the voice pass-through module in response to the speech detection module detecting the headset user talking, when uplink audio is off.

In an embodiment, alternatively or in addition to the above described embodiments, the controller is further configured to deactivate the voice pass-through module in response to one of: a user input, and a predetermined time limit being exceeded without the speech detection module detecting the headset user still talking.

In an embodiment, alternatively or in addition to the above described embodiments, the first audio signal is present and its associated application type comprises call audio, the uplink audio being off comprises the uplink audio being muted, and the controller is further configured to deactivate the voice pass-through module in response to the uplink audio being unmuted.

In an embodiment, alternatively or in addition to the above described embodiments, the first audio signal is present and its associated application type comprises non-call audio, and the uplink audio being off comprises the uplink audio being absent.

In an embodiment, alternatively or in addition to the above described embodiments, the controller is further configured to pause the first audio signal while the voice pass-through module is activated.

In an embodiment, alternatively or in addition to the above described embodiments, the first audio signal is absent, and the uplink audio being off comprises the uplink audio being absent,

In an embodiment, alternatively or in addition to the above described embodiments, the earpiece is configured to output the audio based on both the first audio signal and the second audio signal, and the controller is further configured to one of increase and decrease the volume level of at least one of the first audio signal or the second audio signal while the voice pass-through module is activated.

In an embodiment, alternatively or in addition to the above described embodiments, the speech detection module comprises a sound sensor.

In an embodiment, alternatively or in addition to the above described embodiments, the controller is further configured to determine the associated application type based on information about a connection interface utilized between the headset and the host device.

An embodiment of an apparatus comprises a voice pass-through module configured to pass external voices captured with a headset microphone as a second audio signal to a headset earpiece when the voice pass-through module is activated, audio output by the headset earpiece being noise reduced and based on one or more of the following: a first audio signal from a connected host device and associated with an application type and the second audio signal from the headset microphone, when present; and a controller configured to activate the voice pass-through module in response to receiving an indication from a headset speech detection module that a headset user is talking, when uplink audio is off.

In an embodiment, alternatively or in addition to the above described embodiments, the first audio signal is present and its associated application type comprises call audio, the uplink audio being off comprises the uplink audio being muted, and the controller is further configured to deactivate the voice pass-through module in response to one of: a user input, a predetermined time limit being exceeded without the speech detection module detecting the headset user still talking, and the uplink audio being unmuted.

In an embodiment, alternatively or in addition to the above described embodiments, the first audio signal is present and its associated application type comprises non-call audio, the uplink audio being off comprises the uplink audio being absent, and the controller is further configured to deactivate the voice pass-through module in response to one of: a user input and a predetermined time limit being exceeded without the speech detection module detecting the headset user still talking.

In an embodiment, alternatively or in addition to the above described embodiments, the first audio signal is absent, the uplink audio being off comprises the uplink audio being absent, and the controller is further configured to deactivate the voice pass-through module in response to one of: a user input and a predetermined time limit being exceeded without the speech detection module detecting the headset user still talking.

An embodiment of a method comprises outputting, by a headset earpiece, noise reduced audio based on one or more of the following: a first audio signal from a connected host device and associated with an application type and a second audio signal from a headset microphone, when present; receiving, at the headset controller, an indication from a headset speech detection module that a headset user is talking; and in response, activating by the headset controller a voice pass-through module to pass external voices captured with the headset microphone as the second audio signal to the headset earpiece, when uplink audio is off.

In an embodiment, alternatively or in addition to the above described embodiments, the method further comprises deactivating the voice pass-through module in response to one of: a user input, and a predetermined time limit being exceeded without the speech detection module detecting the headset user still talking.

In an embodiment, alternatively or in addition to the above described embodiments, the first audio signal is present and its associated application type comprises call audio, the uplink audio being off comprises the uplink audio being muted, and the method further comprises deactivating the voice pass-through module in response to the uplink audio being unmuted.

In an embodiment, alternatively or in addition to the above described embodiments, the first audio signal is present and its associated application type comprises non-call audio, and the uplink audio being off comprises the uplink audio being absent.

In an embodiment, alternatively or in addition to the above described embodiments, the method further comprises pausing the first audio signal while the voice pass-through module is activated.

In an embodiment, alternatively or in addition to the above described embodiments, the first audio signal is absent, and the uplink audio being off comprises the uplink audio being absent.

In an embodiment, alternatively or in addition to the above described embodiments, the audio is output based on both the first audio signal and the second audio signal, and the method further comprises one of increasing and decreasing the volume level of at least one of the first audio signal or the second audio signal while the voice pass-through module is activated.

The embodiments illustrated and described herein as well as embodiments not specifically described herein but within the scope of aspects of the disclosure constitute exemplary means for performing automatic selective voice pass-through for a headset. For example, the elements illustrated in FIG. 1 to FIG. 2 constitute exemplary means for outputting, by a headset earpiece, noise reduced audio based on one or more of the following: a first audio signal from a connected host device and associated with an application type and a second audio signal from a headset microphone, when present; exemplary means for receiving an indication from a headset speech detection module that a headset user is talking; and exemplary means for activating, in response, a voice pass-through module to pass external voices captured with the headset microphone as the second audio signal to the headset earpiece, when uplink audio is off.

The term ‘computer’ or ‘computing-based device’ is used herein to refer to any device with processing capability such that it can execute instructions. Those skilled in the art will realize that such processing capabilities are incorporated into many different devices and therefore the terms ‘computer’ and ‘computing-based device’ each include mobile telephones (including smart phones), tablet computers and many other devices.

The processes described herein may be performed by software in machine readable form on a tangible storage medium e.g. in the form of a computer program comprising computer program code means adapted to perform all the steps of any of the processes described herein when the program is run on a computer and where the computer program may be embodied on a computer readable medium. Examples of tangible storage media include computer-readable media such as disks, thumb drives, memory etc. and do not include propagated signals. The software can be suitable for execution on a parallel processor or a serial processor such that the method steps may be carried out in any suitable order, or simultaneously.

This acknowledges that software can be a valuable, separately tradable commodity. It is intended to encompass software, which runs on or controls “dumb” or standard hardware, to carry out the desired functions. It is also intended to encompass software which “describes” or defines the configuration of hardware, such as HDL (hardware description language) software, as is used for designing silicon chips, or for configuring universal programmable chips, to carry out desired functions.

Those skilled in the art will realize that storage devices utilized to store program instructions can be distributed across a network. For example, a remote computer may store an example of the process described as software. A local or terminal computer may access the remote computer and download a part or all of the software to run the program. Alternatively, the local computer may download pieces of the software as needed, or execute some software instructions at the local terminal and some at the remote computer (or computer network). Those skilled in the art will also realize that by utilizing conventional techniques known to those skilled in the art that all, or a portion of the software instructions may be carried out by a dedicated circuit, such as a digital signal processor (DSP), programmable logic array, or the like.

Alternatively, or in addition, the functionality described herein can be performed, at least in part, by one or more hardware logic components. For example, and without limitation, illustrative types of hardware logic components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), and the like.

Any range or device value given herein may be extended or altered without losing the effect sought, as will be apparent to the skilled person.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims, and other equivalent features and acts are intended to be within the scope of the claims.

It will be understood that the benefits and advantages described above may relate to one embodiment or may relate to several embodiments. The embodiments are not limited to those that solve any or all of the stated problems or those that have any or all of the stated benefits and advantages. It will further be understood that reference to ‘an’ item refers to one or more of those items.

Aspects of any of the examples described above may be combined with aspects of any of the other examples described to form further examples without losing the effect sought.

The term ‘comprising’ is used herein to mean including the blocks or elements identified, but that such blocks or elements do not comprise an exclusive list, and a system, a device or an apparatus may contain additional blocks or elements.

It will be understood that the above description is given by way of example only and that various modifications may be made by those skilled in the art. The above specification, examples and data provide a complete description of the structure and use of exemplary embodiments. Although various embodiments have been described above with a certain degree of particularity, or with reference to one or more individual embodiments, those skilled in the art could make numerous alterations to the disclosed embodiments without departing from the spirit or scope of this specification. In particular, the individual features, elements, or parts described in the context of one example, may be connected in any combination to any other example also.

1. A headset, comprising:
a microphone;
an earpiece configured to output audio based on one or more of the following: a first audio signal from a connected host device and associated with an application type and a second audio signal from the microphone, when present;
a processor configured to act as:
a noise reduction module configured to reduce ambient noise;
a speech detection module configured to detect whether a headset user is talking; and
a voice pass-through module configured to pass external voices captured with the microphone as the second audio signal to the earpiece, when activated, the external voices being voices not from the headset user; and
a controller configured to activate the voice pass-through module in response to the speech detection module detecting the headset user talking, when uplink audio is off.

2. The headset as claimed in claim 1, wherein the controller is further configured to deactivate the voice pass-through module in response to one of: a user input, and a predetermined time limit being exceeded without the speech detection module detecting the headset user still talking.

3. The headset as claimed in claim 1, wherein the first audio signal is present and its associated application type comprises call audio, the uplink audio being off comprises the uplink audio being muted, and the controller is further configured to deactivate the voice pass-through module in response to the uplink audio being unmuted.

4. The headset as claimed in claim 1, wherein the first audio signal is present and its associated application type comprises non-call audio, and the uplink audio being off comprises the uplink audio being absent.

5. The headset as claimed in claim 4, wherein the controller is further configured to pause the first audio signal while the voice pass-through module is activated.

6. The headset as claimed in claim 1, wherein the first audio signal is absent, and the uplink audio being off comprises the uplink audio being absent,

7. The headset as claimed in claim 1, wherein the earpiece is configured to output the audio based on both the first audio signal and the second audio signal, and the controller is further configured to one of increase and decrease the volume level of at least one of the first audio signal or the second audio signal while the voice pass-through module is activated.

8. The headset as claimed in claim 1, wherein the speech detection module comprises a sound sensor and the external voices are voices nearby the headset.

9. The headset as claimed in claim 1, wherein the controller is further configured to determine the associated application type based on information about a connection interface utilized between the headset and the host device.

10. An apparatus, comprising:
a processor configured to act as a voice pass-through module configured to pass external voices captured with a headset microphone as a second audio signal to a headset earpiece when the voice pass-through module is activated, the external voices not from a headset user, and audio output by the headset earpiece being noise reduced and based on one or more of the following: a first audio signal from a connected host device and associated with an application type and the second audio signal from the headset microphone, when present; and
a controller configured to activate the voice pass-through module in response to receiving an indication from a headset speech detection module that the headset user is talking, when uplink audio is off.

11. The apparatus as claimed in claim 10, wherein the first audio signal is present and its associated application type comprises call audio, the uplink audio being off comprises the uplink audio being muted, and the controller is further configured to deactivate the voice pass-through module in response to one of: a user input, a predetermined time limit being exceeded without the speech detection module detecting the headset user still talking, and the uplink audio being unmuted.

12. The apparatus as claimed in claim 10, wherein the first audio signal is present and its associated application type comprises non-call audio, the uplink audio being off comprises the uplink audio being absent, and the controller is further configured to deactivate the voice pass-through module in response to one of: a user input and a predetermined time limit being exceeded without the speech detection module detecting the headset user still talking.

13. The apparatus as claimed in claim 10, wherein the first audio signal is absent, the uplink audio being off comprises the uplink audio being absent, and the controller is further configured to deactivate the voice pass-through module in response to one of: a user input and a predetermined time limit being exceeded without the speech detection module detecting the headset user still talking.

14. A method, comprising:
outputting, by a headset earpiece, noise reduced audio based on one or more of the following: a first audio signal from a connected host device and associated with an application type and a second audio signal from a headset microphone, when present;
receiving, at a headset controller, an indication from a headset speech detection module that a headset user is talking; and
in response, activating by the headset controller a voice pass-through module to pass external voices captured with the headset microphone as the second audio signal to the headset earpiece, when uplink audio is off the external voices not from the headset user.

15. The method as claimed in claim 14, further comprising deactivating the voice pass-through module in response to one of: a user input, and a predetermined time limit being exceeded without the speech detection module detecting the headset user still talking.

16. The method as claimed in claim 14, wherein the first audio signal is present and its associated application type comprises call audio, the uplink audio being off comprises the uplink audio being muted, and the method further comprises deactivating the voice pass-through module in response to the uplink audio being unmuted.

17. The method as claimed in claim 14, wherein the first audio signal is present and its associated application type comprises non-call audio, and the uplink audio being off comprises the uplink audio being absent.

18. The method as claimed in claim 17, further comprising pausing the first audio signal while the voice pass-through module is activated.

19. The method as claimed in claim 14, wherein the first audio signal is absent, and the uplink audio being off comprises the uplink audio being absent.

20. The method as claimed in claim 14, wherein the audio is output based on both the first audio signal and the second audio signal, and the method further comprises one of increasing and decreasing the volume level of at least one of the first audio signal or the second audio signal while the voice pass-through module is activated.
